(19) United States
(12) Patent Application Publication
(10) Pub. No.: US 2026/0342288 A1
(43) Pub. Date: Oct. 29, 2026

(54) LOW-NOISE AMPLIFIER CIRCUIT

(71) Applicant: Murata Manufacturing Co., Ltd., Nagaokakyo-shi (JP)

(72) Inventor: Ikumi TOKUDA, Nagaokakyo-shi (JP)

(73) Assignee: Murata Manufacturing Co., Ltd., Nagaokakyo-shI (JP)

(21) Appl. No.: 19/647,915

(22) Filed: Apr. 15, 2026

(30) Foreign Application Priority Data
Apr. 24, 2025 (JP) 2025-072401

(51) Int. Cl. H03F 1/32; H03F 3/19

(52) U.S. Cl. CPC H03F 1/32; H03F 3/19; H03F 2200/294

(57) ABSTRACT

A low-noise amplifier circuit includes an input terminal, an output terminal, an amplifier connected between the input terminal and the output terminal, a transmission line transformer including first and second inductors connected between the input terminal and an input end of the amplifier, and a third inductor connected between a ground connection end of the amplifier and ground. A first end of the first inductor and a first end of the second inductor are connected to the input terminal. A second end of the first inductor is connected to the input end of the amplified. A second end of the second inductor is connected to ground. A coupling coefficient between the second and third inductors is greater than a coupling coefficient between the first and third inductors.

### CROSS-REFERENCE TO RELATED APPLICATION

This application claims priority under 35 U.S.C. § 119 to Japanese Patent Application No. 2025-072401, filed on Apr. 24, 2025, the entire contents of which are incorporated herein by reference.

### BACKGROUND

### 1. Field

The present disclosure relates to a low-noise amplifier circuit.

### 2. Description of the Related Art

U.S. Patent Application Publication No. 2017/0194918 discloses a low-noise amplifier circuit including a common-source amplifier, a first inductor connected between an input terminal and a gate end of the common-source amplifier, and a second inductor connected to a source end of the common-source amplifier. The low-noise amplifier circuit is configured to improve its linearity by magnetically coupling the first inductor and the second inductor.

### SUMMARY

A low-noise amplifier circuit according to one aspect of the present invention includes: an input terminal; an output terminal; an amplifier connected between the input terminal and the output terminal; a transmission line transformer including a first inductor and a second inductor and connected between the input terminal and an input end of the amplifier; and a third inductor connected between a ground connection end of the amplifier and ground. A first end of the first inductor and a first end of the second inductor are connected to the input terminal. A second end of the first inductor is connected to the input end of the amplifier. A second end of the second inductor is connected to ground. A coupling coefficient between the second inductor and the third inductor is greater than a coupling coefficient between the first inductor and the third inductor.

A low-noise amplifier circuit according to one aspect of the present disclosure includes: a substrate; an input terminal; an output terminal; an amplifier connected between the input terminal and the output terminal; a transmission line transformer including a first inductor and a second inductor and connected between the input terminal and an input end of the amplifier; and a third inductor connected between a ground connection end of the amplifier and ground. A first end of the first inductor and a first end of the second inductor are connected to the input terminal. A second end of the first inductor is connected to the input end of the amplifier. A second end of the second inductor is connected to ground. The first inductor is formed by a first wiring line disposed in or on the substrate. The second inductor is formed by a coil-shaped second wiring line disposed in or on the substrate. The third inductor is formed by a third wiring line disposed in or on the substrate. One of the first wiring line and the third wiring line is disposed in the inner region of the second wiring line in a plan view of the substrate. The other of the first wiring line and the third wiring line is disposed in the outer region of the second wiring line in a plan view of the substrate.

A low-noise amplifier circuit according to one aspect of the present disclosure includes: a substrate; an input terminal; an output terminal; an amplifier connected between the input terminal and the output terminal; a transmission line transformer including a first inductor and a second inductor and connected between the input terminal and an input end of the amplifier; and a third inductor connected between a ground connection end of the amplifier and ground. A first end of the first inductor and a first end of the second inductor are connected to the input terminal. A second end of the first inductor is connected to the input end of the amplifier. A second end of the second inductor is connected to ground. The first inductor, the second inductor, and the third inductor are formed by wiring lines disposed in or on the substrate. A distance between the second inductor and the third inductor is smaller than a distance between the first inductor and the third inductor.

According to one or more aspects of the present disclosure, the bandwidth of the low-noise amplifier circuit may be broadened.

### BRIEF DESCRIPTION OF THE DRAWINGS

FIG. 1 is a circuit configuration diagram of a low-noise amplifier circuit according to an embodiment;

FIG. 2 is a circuit configuration diagram of a low-noise amplifier circuit according to Modification Example 1 of the embodiment;

FIG. 3A is a plan view of the low-noise amplifier circuit according to the embodiment;

FIG. 3B is a cross-sectional view of the low-noise amplifier circuit according to the embodiment;

FIG. 4 is a plan view of a low-noise amplifier circuit according to Modification Example 2 of the embodiment;

FIG. 5 is a plan view of a low-noise amplifier circuit according to Modification Example 3 of the embodiment;

FIG. 6 is a plan view of a low-noise amplifier circuit according to Modification Example 4 of the embodiment;

FIG. 7 is a plan view of a low-noise amplifier circuit according to Modification Example 5 of the embodiment;

FIG. 8A is a plan view of a low-noise amplifier circuit according to Modification Example 6 of the embodiment; and

FIG. 8B is a cross-sectional view of the low-noise amplifier circuit according to Modification Example 6 of the embodiment.

### DESCRIPTION OF THE EMBODIMENTS

The inventor has realized that, in the above-described conventional technology, however, magnetic coupling between the first inductor and the second inductor causes the two inductors to function as a low-pass filter. As a result, the amplification characteristics at higher frequencies may deteriorate, making it difficult to achieve broadband operation.

According to present disclosure, one or more embodiments are directed to providing a low-noise amplifier circuit capable of broadband operation.

Hereinafter, embodiments will be described in detail using the drawings. Note that the embodiment described below is provided only as an example, whether broadly or specifically defined. The numerical values, shapes, materials, components, arrangement and connection forms of the components, and the like described in the following embodiment are merely examples and are not intended to limit the present disclosure.

Note that the drawings are schematic diagrams in which certain components have been appropriately emphasized, omitted, or scaled for the purpose of illustrating the present disclosure. Accordingly, they are not necessarily depicted with strict accuracy and may differ from the actual shapes, positional relationships, and proportions. In the drawings, the same reference numerals are given to substantially identical configurations, and repeated explanations may be omitted or simplified.

In the following drawings, the x-axis and y-axis are axes orthogonal to each other on a plane parallel to the main surface of the substrate. The z-axis is an axis perpendicular to the main surface of the substrate, the positive direction of which indicates the upward direction, and the negative direction of which indicates the downward direction.

In the following description, the term “connected” includes not only cases in which elements are directly connected by a connection terminal and/or a wiring conductor, but also cases in which they are electrically coupled with another circuit element interposed therebetween.

The phrase “C is connected between A and B” means that a first end of C is connected to A and a second end of C is connected to B, i.e., C is connected in series with a path connecting A and B. The phrase “C is connected between a path connecting A and B and ground” means that a first end of C is connected to a path connecting A and B and a second end of C is connected to ground, i.e., C is connected in shunt to a path connecting A and B. The phrase “path connecting A and B” refers to a path composed of a conductor electrically coupling A to B. Further, “ground” includes a reference potential, a chassis ground, a common return path, or a virtual ground.

The term “terminal” refers to a point at which a conductor within a circuit element terminates. When the impedance of a conductor between circuit elements is sufficiently low, a terminal is interpreted not only as a single point but also as any point on the conductor between the circuit elements, or as the entire conductor. The term “node” refers to a point between circuit elements. When the impedance of a conductor between circuit elements is sufficiently low, a node is interpreted not only as a single point but also as any point on the conductor between the circuit elements, or as the entire conductor.

The phrase “a wiring line is disposed in or on the substrate” includes both cases in which a wiring line is disposed on the main surface of the substrate and where a wiring line is disposed in the substrate. The phrase “a wiring line is disposed on the main surface of the substrate” includes cases in which a wiring line is disposed in contact with the main surface of the substrate as well as cases in which a wiring line is disposed above the main surface without being in contact with the main surface (e.g., a wiring line is stacked on another component disposed in contact with the main surface). Additionally, the phrase “a wiring line is disposed on the main surface of the substrate” may also include cases in which a wiring line is disposed in a recess formed in the main surface. The phrase “a wiring line is disposed in the substrate” includes cases in which a wiring line is encapsulated in the substrate, cases in which the entire wiring line is disposed between the two main surfaces of the substrate but a portion of the wiring line is not covered by the substrate, and cases in which only a part of the wiring line is disposed in the substrate.

The phrase “a plan view of the substrate” means viewing an object orthogonally projected onto the xy-plane in the negative z-axis direction. The phrase “A overlaps B in a plan view of the substrate” means that the region of A orthogonally projected onto the xy-plane overlaps the region of B orthogonally projected onto the xy-plane.

The phrase “A is directly connected to B” means that A is connected to B in physical contact. Note that the phrase “A is directly connected to B” also includes cases in which A is connected to B with a joining material interposed therebetween. The term “joining material” refers to a substance interposed between A and B for physically connecting (joining) A and B.

Terms indicating relationships between elements, such as “parallel” and “perpendicular”, and terms indicating the shapes of elements, such as “straight line”, as well as numerical ranges, do not only denote strict meanings but also include substantially equivalent ranges, for example, with an error of several percent.

### Embodiment

### 1. Circuit Configuration of Low-Noise Amplifier Circuit 1

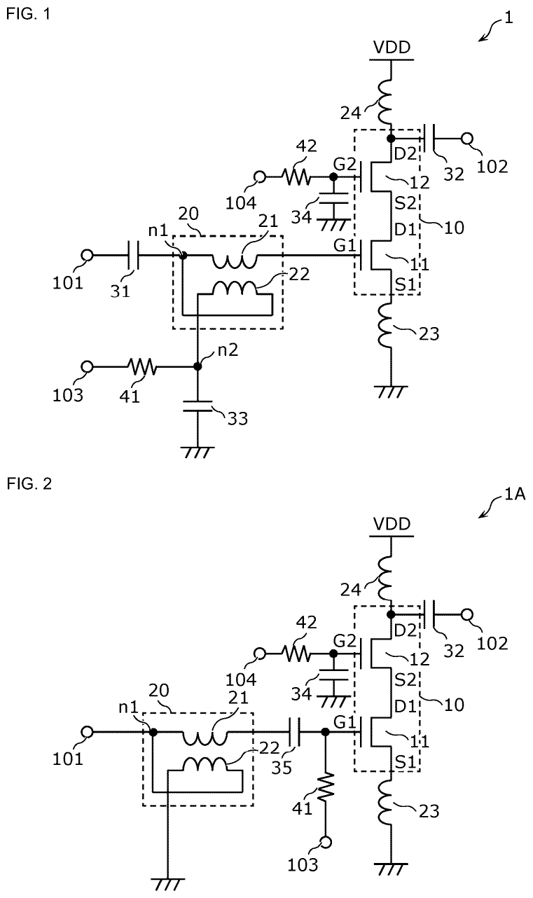

FIG. 1 is a circuit configuration diagram of a low-noise amplifier circuit 1 according to the embodiment. Note that FIG. 1 is an exemplary circuit configuration diagram, and the low-noise amplifier circuit 1 may be implemented using any of various circuit implementations and circuit technologies. Accordingly, the following description of the low-noise amplifier circuit 1 is not to be construed as limiting.

The low-noise amplifier circuit 1 includes an input terminal 101, an output terminal 102, bias terminals 103 and 104, an amplifier 10, a transmission line transformer 20, inductors 23 and 24, capacitors 31, 32, 33 and 34, and resistors 41 and 42. As used herein “inductor” or “wiring line” encompasses any inductive element, including spiral inductors, meander lines, bond wires, or parasitic inductances that are intentionally tuned to affect coupling coefficients.

The input terminal 101 is an external connection terminal of the low-noise amplifier circuit 1 and is a terminal for receiving high-frequency signals. The input terminal 101 is connected to, for example, an antenna outside the low-noise amplifier circuit 1, and to the capacitor 31 inside the low-noise amplifier circuit 1.

The output terminal 102 is an external connection terminal of the low-noise amplifier circuit 1 and is a terminal for supplying high-frequency signals. The output terminal 102 is connected to, for example, an RFIC (Radio Frequency Integrated Circuit) outside the low-noise amplifier circuit 1, and to the capacitor 32 inside the low-noise amplifier circuit 1.

The amplifier 10 is capable of amplifying high-frequency signals using a power supply voltage VDD supplied from a power supply. The amplifier 10 is connected between the input terminal 101 and the output terminal 102. Specifically, an input end of the amplifier 10 is connected to the input terminal 101 with the capacitor 31 and the transmission line transformer 20 interposed therebetween. An output end of the amplifier 10 is connected to the output terminal 102 with the capacitor 32 interposed therebetween, and is also connected to the power supply with the inductor 24 interposed therebetween. A ground connection end of the amplifier 10 is connected to ground with the inductor 23 interposed therebetween.

The amplifier 10 includes FETs 11 and 12 connected in a cascode configuration. The FET 11 is an example of a first FET, and it includes a gate end G1, a drain end D1, and a source end S1. The gate end G1 is the input end of the amplifier 10, and the source end S1 is the ground connection end of the amplifier 10. The drain end D1 is connected to a source end S2 of the FET 12. The FET 12 is an example of a second FET, and it includes a gate end G2, a drain end D2, and the source end S2. The gate end G2 is connected to the bias terminal 104 with the resistor 42 interposed therebetween, and is connected to ground with the capacitor 34 interposed therebetween. The drain end D2 is the output end of the amplifier 10.

The FETs 11 and 12 are, for example, Field Effect Transistors, and more specifically, MOSFETs (Metal Oxide Semiconductor Field Effect Transistors). Note that the FETs 11 and 12 are not limited to field effect transistors. The FETs 11 and 12 may be bipolar transistors.

The inductor 23 is an example of a third inductor and is a so-called source inductor, and it is connected between the ground connection end of the amplifier 10 and ground. The inductance value of the inductor 23 is, for example, 0.1 nH to 1 nH.

The inductor 24 is a so-called choke inductor and is connected between the power supply and the FET 12.

The transmission line transformer 20 includes inductors 21 and 22. The transmission line transformer 20 is connected between the input terminal 101 and the input end of the amplifier 10. By electromagnetically coupling the inductors 21 and 22, the transmission line transformer 20 is able to shift the phase and convert the impedance.

The inductor 21 is an example of a first inductor and is a so-called main line of the transmission line transformer 20. The inductor 22 is an example of a second inductor and is a so-called sub line of the transmission line transformer 20. The inductors 21 and 22 are configured to be magnetically couplable to each other. A first end of the inductor 21 and a first end of the inductor 22 are connected at a node n1. The first end of the inductor 21 and the first end of the inductor 22 are connected to the input terminal 101 with the capacitor 31 interposed therebetween. A second end of the inductor 21 is connected to the input end of the amplifier 10. A second end of the inductor 22 is connected to ground with the capacitor 33 interposed therebetween. The second end of the inductor 22 is connected at a node n2 to the bias terminal 103 with the resistor 41 interposed therebetween. The inductance values of the inductors 21 and 22 are, for example, 1 nH to 10 nH.

The low-noise amplifier circuit 1 is capable of amplifying high-frequency signals in, for example, the WLAN 7 GHz band (WiFi® 7 GHz band). In this case, the inductance value of the inductor 21 is, for example, 1.1 nH, the inductance value of the inductor 22 is, for example, 1.6 nH, and the inductance value of the inductor 23 is, for example, 0.2 nH. While the embodiments are described with reference to the 7 GHz band, the principles of the disclosure are applicable to other radio frequency bands, including Sub-6 GHz, mmWave, and satellite communication frequencies.

The capacitor 31 is an example of a first capacitor and is connected between the input terminal 101 and the first end of the inductor 21. The capacitor 31 is a so-called coupling capacitor, and in the path connecting the input terminal 101 and the amplifier 10, it allows high-frequency components to pass while blocking direct-current (DC) components.

The capacitor 33 is an example of a second capacitor and is connected between the second end of inductor 22 and the bias terminal 103, and ground. The capacitor 33 is capable of blocking DC components in the path connecting the inductor 22 and ground.

The capacitor 34 is connected between the gate end G2 of the FET 12 and ground. The capacitor 32 is connected between the path connecting the FET 12 and the inductor 24 and the output terminal 102.

In the low-noise amplifier circuit 1 with the above-described circuit configuration, a coupling coefficient k23 indicating the degree of magnetic coupling between the inductors 22 and 23 is greater than a coupling coefficient k13 indicating the degree of magnetic coupling between the inductors 21 and 23.

By magnetically coupling the inductors 22 and 23, a high-frequency signal input to the amplifier 10 is fed back from the inductor 23 to the inductor 22, thereby forming a high-pass filter in the signal transmission path between the inductors 22 and 23. Accordingly, the bandwidth of the amplification characteristics of the low-noise amplifier circuit 1 may be broadened.

On the other hand, when the inductors 21 and 23 are magnetically coupled, a high-frequency signal input to the amplifier 10 is fed back from the inductor 23 to the inductor 21. As a result, an equivalent series resistor is inserted into the signal transmission path between the inductors 21 and 23, thereby forming a low-pass filter. Accordingly, the amplification characteristics at higher frequencies are deteriorated, making it difficult to broaden the bandwidth.

According to the low-noise amplifier circuit 1 according to the present embodiment, since the coupling coefficient k13 is smaller than the coupling coefficient k23, a low-pass filter is suppressed from being formed between the inductors 23 and 21. Additionally, since the coupling coefficient k23 is greater than the coupling coefficient k13, good linearity up to higher frequencies by the feedback loop between the inductors 23 and 22 may be realized, allowing the bandwidth of the amplification characteristics of the low-noise amplifier circuit 1 to be broadened. In other words, by configuring the first, second, and third inductors such that the magnetic coupling between the second inductor and the third inductor is greater than the magnetic coupling between the first inductor and the third inductor, a frequency-dependent feedback loop is created. Specifically, the magnetic coupling between the second inductor (which functions as a sub-line of the transmission line transformer) and the third inductor (connected to the ground connection end of the amplifier) generates a high-pass feedback characteristic. This high-pass feedback at least partially compensates for the low-pass filter characteristics inherent in the magnetic coupling between the first and second inductors of the transmission line transformer. Consequently, the low-noise amplifier circuit maintains high linearity and gain at higher operational frequencies while extending the effective operational bandwidth compared to conventional coupled-inductor topologies.

Note that a coupling coefficient k12 indicating the degree of magnetic coupling between the inductors 21 and 22 may be greater than the coupling coefficient k23 between the inductors 22 and 23. This ensures a greater degree of freedom in phase shifting and impedance transformation in the transmission line transformer 20.

It should be noted that the inductor 24, the capacitors 31 to 34, the resistors 41 and 42, and the bias terminals 103 and 104 need not be included in the low-noise amplifier circuit 1.

Additionally, the amplifier 10 is not limited to a source-grounded amplifier. For example, the amplifier 10 may be a gate-grounded amplifier.

Furthermore, the amplifier 10 need not include the FETs 11 and 12 connected in a cascode configuration. For example, the amplifier 10 may include the FET 11 but not the FET 12. In this case, the FET 11 is an example of the first FET; the gate end of the FET 11 is the input end of the amplifier 10; the source end of the FET 11 is the ground connection end of the amplifier 10; and the drain end of the FET 11 is the output end of the amplifier 10. Additionally, the bias terminal 104, the resistor 42, and the capacitor 34 are not disposed.

In the circuit configuration of the amplifier 10, other circuit elements and wiring may be inserted in the paths connecting the circuit elements and signal paths disclosed in FIG. 1. For example, a capacitor may be connected between the drain end D2 and the gate end G2 of the FET 12.

### 2. Circuit Configuration of Low-Noise Amplifier Circuit 1A According to Modification Example 1

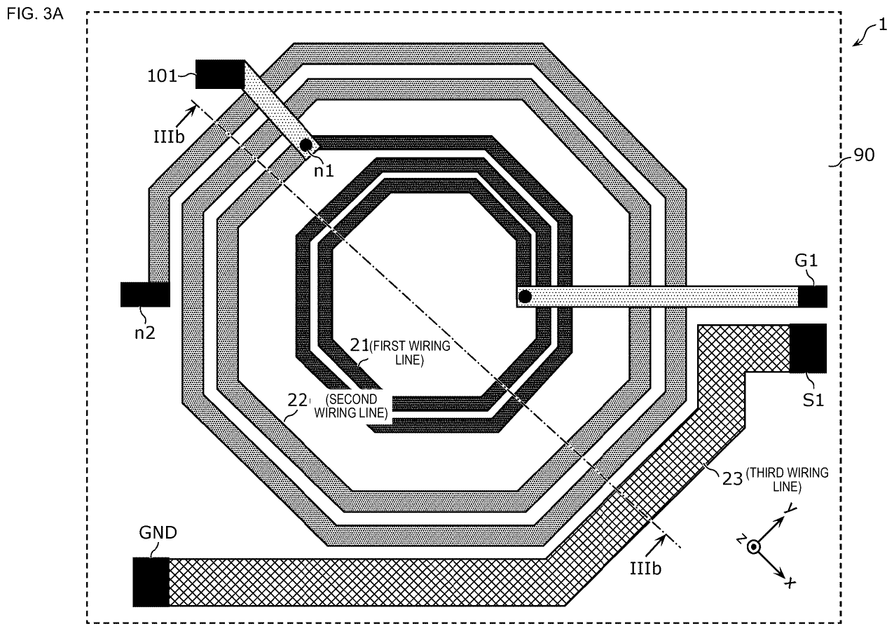

FIG. 2 is a circuit configuration diagram of a low-noise amplifier circuit 1A according to Modification Example 1 of the embodiment. As illustrated in the diagram, the low-noise amplifier circuit 1A according to the present modification example includes the input terminal 101, the output terminal 102, the bias terminals 103 and 104, the amplifier 10, the transmission line transformer 20, the inductors 23 and 24, the capacitors 32, 34, and 35, and the resistors 41 and 42. The low-noise amplifier circuit 1A according to the present modification example differs from the low-noise amplifier circuit 1 according to the embodiment in the configuration for supplying a bias voltage to the FET 11. Therefore, in the following description of the low-noise amplifier circuit 1A according to the present modification example, explanation of configurations identical to those of the low-noise amplifier circuit 1 according to the embodiment will be omitted, and the description will focus on the bias-voltage supply configuration that differs from the low-noise amplifier circuit 1 according to the present embodiment.

The input terminal 101 is connected to an antenna outside the low-noise amplifier circuit 1A, and to the transmission line transformer 20 inside the low-noise amplifier circuit 1A.

The input end of the amplifier 10 is connected to the input terminal 101 with the capacitor 35 and the transmission line transformer 20 interposed therebetween. The input end of the amplifier 10 is connected to the bias terminal 103 with the resistor 41 interposed therebetween.

The first end of the inductor 21 and the first end of the inductor 22 are connected to the input terminal 101. The second end of the inductor 21 is connected to the input end of the amplifier 10 with the capacitor 35 interpreted therebetween. The second end of the inductor 22 is connected to ground.

The capacitor 35 is an example of the first capacitor and is connected between the second end of the inductor 21 and the input end of the amplifier 10. The capacitor 35 is a so-called coupling capacitor, and in the path connecting the input terminal 101 and the amplifier 10, it allows high-frequency components to pass while blocking DC components.

In the low-noise amplifier circuit 1A with the above-described circuit configuration, the coupling coefficient k23 between the inductors 22 and 23 is greater than the coupling coefficient k13 between the inductors 21 and 23.

According to this, since the coupling coefficient k13 is smaller than the coupling coefficient k23, it is possible to prevent a low-pass filter from being formed between the inductors 23 and 21. Additionally, since the coupling coefficient k23 is greater than the coupling coefficient k13, a high-pass filter is formed between the inductors 23 and 22. By Thus, good linearity up to higher frequencies by the feedback loop formed by electromagnetic coupling between the inductors 23 and 22 may be realized, allowing the bandwidth of the amplification characteristics of the low-noise amplifier circuit 1A to be broadened.

Note that it is possible to determine the coupling coefficient between two inductors in the embodiment and the modification example by obtaining factors such as the inductance values of the respective inductors, the directions of magnetic flux of the inductors, the distance between the two inductors, and the material properties of the surrounding region of the two inductors. For example, when the two inductors are formed by wiring lines disposed in or on a substrate 90, it is possible to calculate the coupling coefficient using an electromagnetic field simulator by inputting parameters such as the layout of the two inductors disposed in or on the substrate 90 and the material properties of the two inductors and the substrate 90.

### 3. Implementation Example of Inductors 21, 22, and 23 According to Embodiment

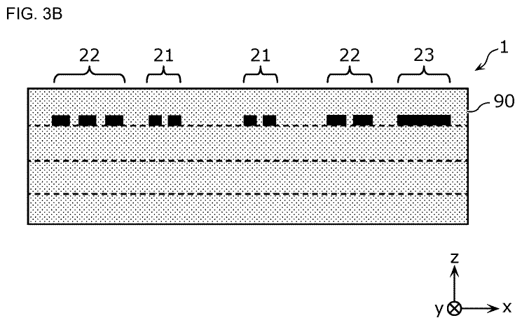

Next, an implementation example of the inductors 21 to 23 included in the low-noise amplifier circuit 1 will be described with reference to FIGS. 3A and 3B. FIG. 3A is a plan view of the low-noise amplifier circuit 1 according to the embodiment. FIG. 3B is a cross-sectional view of the low-noise amplifier circuit 1 according to the embodiment. Specifically, FIG. 3A is a plan (perspective) view of the region in which the inductors 21 to 23 of the substrate 90 are formed, as viewed from the positive z-axis side, and FIG. 3B is a cross-sectional view taken along line IIIb-IIIb of FIG. 3A.

Note that FIGS. 3A and 3B represent exemplary configurations of the inductors 21, 22, and 23, and the inductors 21 to 23 may be implemented using any of various circuit implementations and circuit technologies. Accordingly, the following description of the inductors 21 to 23 is not to be construed as limiting.

As illustrated in FIGS. 3A and 3B, the low-noise amplifier circuit 1 includes the substrate 90 in addition to the circuit configuration illustrated in FIG. 1.

The substrate 90 is, for example, a substrate made of a semiconductor material and may also be referred to as a die or chip. Examples of the semiconductor material include monocrystalline silicon, gallium nitride (GaN), and silicon carbide (SiC).

The substrate 90 may be, for example, a substrate formed of a ceramic body produced by low-temperature co-firing of a laminate of multiple dielectric layers (LTCC: Low Temperature Co-fired Ceramics), a substrate formed of a ceramic body produced by high-temperature co-firing (HTCC: High Temperature Co-fired Ceramics), a component-embedded substrate, a substrate having a redistribution layer (RDL), or a printed circuit board.

As illustrated in FIG. 3A, the inductor 21 is formed by a coil-shaped first wiring line disposed in or on the substrate 90. Additionally, the inductor 22 is formed by a coil-shaped second wiring line disposed in or on the substrate 90. Furthermore, the inductor 23 is formed by a third wiring line disposed in or on the substrate 90. As illustrated in FIG. 3B, the inductors 21 to 23 are formed in an identical layer of the substrate 90.

Specifically, the inductor 21 is formed by a first wiring line that extends in a clockwise spiral from the outer side toward the inner side. The inductor 22 is formed by a second wiring line that extends in a counterclockwise spiral from the inner side toward the outer side. The first end of the inductor 21 and the first end of the inductor 22 are connected at the node n1. The second end of the inductor 21 is connected to the gate G1 of the FET 11 with connection wiring interposed therebetween. The second end of the inductor 22 is connected to the node n2. The first end of the inductor 23 is connected to the source end S1 of the FET 11. The second end of the inductor 23 is connected to ground.

Here, as illustrated in FIGS. 3A and 3B, the first wiring line constituting the inductor 21 is disposed in the inner region of the second wiring line constituting the inductor 22. The third wiring line constituting the inductor 23 is disposed in the outer region of the second wiring line.

According to this, in a plan view of the substrate 90, since the inductors 21 and 23 are arranged with the inductor 22 interposed therebetween, it is possible to make the coupling coefficient k23 between the inductors 22 and 23 greater than the coupling coefficient k13 between the inductors 21 and 23. By doing so, it is possible to suppress a low-pass filter from being formed between the inductors 23 and 21, and it is also possible to ensure good linearity up to higher frequencies by the feedback loop formed by magnetic coupling between the inductors 23 and 22. Therefore, it is possible to broaden the bandwidth of the amplification characteristics of the low-noise amplifier circuit 1.

Note that the coupling coefficient k12 indicating the degree of magnetic coupling between the inductors 21 and 22 may be greater than the coupling coefficient k23 between the inductors 22 and 23. This ensures a greater degree of freedom in phase shifting and impedance transformation in the transmission line transformer 20.

Note that each of the inductors 21 to 23 need not be configured by a wiring line formed only in a single layer of the substrate 90, but may instead be configured by multiple wiring lines formed across multiple layers of the substrate 90.

Alternatively, the first wiring line, the second wiring line, and the third wiring line may be formed in different layers of the substrate 90 or at least portions of the first wiring line, the second wiring line, or the third wiring line may be formed in an identical layer of the substrate 90.

Furthermore, the first wiring line need not be coil-shaped, and the third wiring line may be coil-shaped.

Moreover, the winding directions of the inductors 21 and 22 are not limited to the winding directions described above.

In the low-noise amplifier circuit 1 according to the present embodiment, the first wiring line constituting the inductor 21 may be formed in the outer region of the second wiring line constituting the inductor 22, and the third wiring line constituting the inductor 23 may be disposed in the inner region of the second wiring line.

This also allows the inductors 21 and 23 to be arranged with the inductor 22 interposed therebetween in a plan view of the substrate 90, thereby allowing the coupling coefficient k23 between the inductors 22 and 23 to be greater than the coupling coefficient k13 between the inductors 21 and 23. Therefore, it is possible to broaden the bandwidth of the amplification characteristics of the low-noise amplifier circuit 1.

Each of the inductors 21 and 23 may be a surface-mounted chip inductor disposed on the substrate 90.

Note that, in the present embodiment, each of the first wiring line constituting the inductor 21, the second wiring constituting the inductor 22, and the third wiring line constituting the inductor 23 (hereinafter referred to as a wiring line constituting an inductor) is defined as follows. A wiring line constituting an inductor is defined as a portion of a wiring line having a constant line width and a constant film thickness in a plan view of the substrate 90, which is located between via conductors or terminals. However, when an inductor is constituted by multiple wiring lines across multiple layers, the diameter of a via conductor that connects wiring lines in different layers may differ from the line width and film thickness of an intra-layer wiring line, and such via conductors are also included as wiring constituting the inductor.

### 4. Implementation Example of Inductors 21, 22, and 23 According to Modification Example 2

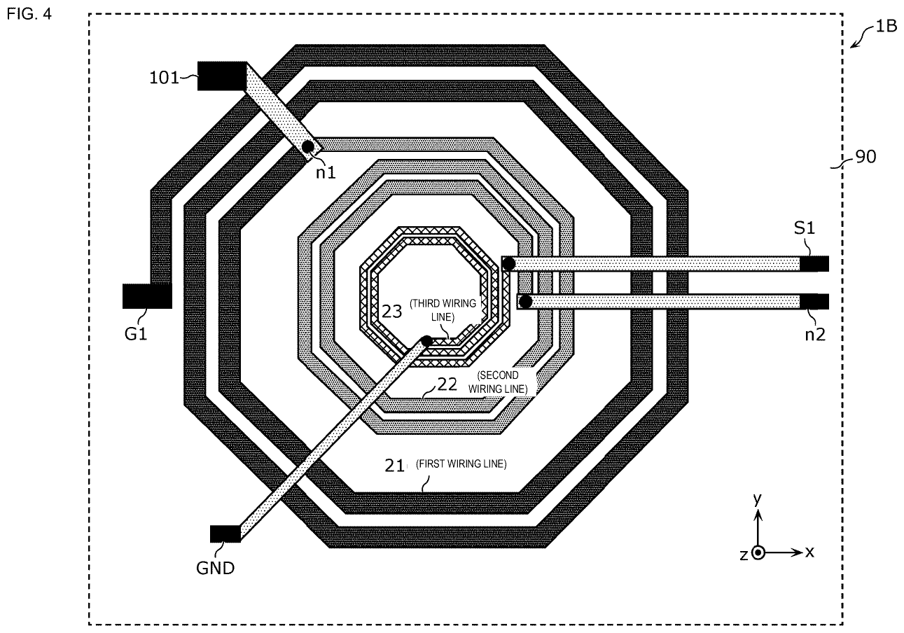

Next, an implementation example of the inductors 21 to 23 included in a low-noise amplifier circuit 1B according to Modification Example 2 will be described with reference to FIG. 4. FIG. 4 is a plan view of the low-noise amplifier circuit 1B according to Modification Example 2 of the embodiment. Specifically, FIG. 4 is a plan (perspective) view of the region in which the inductors 21 to 23 of the substrate 90 are formed, as viewed from the positive z-axis side. As used herein, the term “encompassed within the inner region” refers to a spatial relationship in a plan view where the center point or longitudinal axis of the magnetic flux path of an inductor is located within the area bounded by the innermost winding of another inductor. This encompassing relationship includes configurations where the winding axes are coaxial, as well as configurations where the axes are laterally offset from one another but still remain within the perimeter defined by the surrounding inductor windings.

The low-noise amplifier circuit 1B according to Modification Example 2 has the circuit configuration illustrated in FIG. 1, and differs from the low-noise amplifier circuit 1 according to the embodiment in the arrangement configurations of the inductors 21 to 23. Therefore, in the following description of the low-noise amplifier circuit 1B according to the present modification example, explanation of configurations identical to those of the low-noise amplifier circuit 1 according to the embodiment will not be repeated, and the description will focus on the arrangement configurations of the inductors 21 to 23 that differ from the low-noise amplifier circuit 1 according to the embodiment.

As illustrated in FIG. 4, the low-noise amplifier circuit 1B includes the substrate 90 in addition to the circuit configuration illustrated in FIG. 1.

As illustrated in FIG. 4, the inductor 21 is formed by a coil-shaped first wiring line disposed in or on the substrate 90. Additionally, the inductor 22 is formed by a coil-shaped second wiring line disposed in or on the substrate 90. Additionally, the inductor 23 is formed by a coil-shaped third wiring line disposed in or on the substrate 90. The inductors 21 to 23 are formed in an identical layer of the substrate 90.

Specifically, the inductor 21 is formed by a first wiring line that extends in a clockwise spiral from the outer side toward the inner side. The inductor 22 is formed by a second wiring line that extends in a counterclockwise spiral from the inner side toward the outer side. The first end of the inductor 21 and the first end of the inductor 22 are connected at the node n1. The second end of the inductor 21 is connected to the gate G1 of the FET 11. The second end of the inductor 22 is connected to the node n2 with connection wiring interposed therebetween. The inductor 23 is formed by a third wiring line that extends in a clockwise spiral from the outer side toward the inner side. The first end of the inductor 23 is connected to the source end S1 of the FET 11 with connection wiring interposed therebetween. The second end of the inductor 23 is connected to ground with connection wiring interposed therebetween.

Here, in a plan view of the substrate 90, the winding axis of the inductor 21 and the winding axis of the inductor 23, which extend in the z-axis direction, are encompassed within the inner region of the second wiring line. Moreover, the first wiring line constituting the inductor 21 is disposed in the outer region of the second wiring line constituting the inductor 22. The third wiring line constituting the inductor 23 is disposed in the inner region of the second wiring line.

According to this, in a plan view of the substrate 90, the inductors 21 and 23 are arranged with the inductor 22 interposed therebetween. Furthermore, the area ratio of the inner region of the inductor 23 to the inner region of the inductor 21 is smaller than the area ratio of the inner region of the inductor 23 to the inner region of the inductor 22. Thus, the coupling coefficient k23 between the inductors 22 and 23 may be greater than the coupling coefficient k13 between the inductors 21 and 23. Thus, a low-pass filter may be suppressed from being formed between the inductors 23 and 21, ensuring good linearity up to higher frequencies by the feedback loop formed by magnetic coupling between the inductors 23 and 22. Accordingly, the bandwidth of the amplification characteristics of the low-noise amplifier circuit 1B may be broadened.

Note that each of the inductors 21 to 23 need not be configured by a wiring line formed only in a single layer of the substrate 90, but may instead be configured by multiple wiring lines formed across multiple layers of the substrate 90.

Additionally, the first wiring line, the second wiring line, and the third wiring line may be formed in different layers of the substrate 90 or at least portions of the first wiring line, the second wiring line, or the third wiring line may be formed in an identical layer of the substrate 90.

Moreover, the winding directions of the inductors 21 to 23 are not limited to the winding directions described above.

In the low-noise amplifier circuit 1B according to the present modification example, the first wiring line constituting the inductor 21 may be formed in the inner region of the second wiring line constituting the inductor 22, and the third wiring line constituting the inductor 23 may be disposed in the outer region of the second wiring line.

According to this, in a plan view of the substrate 90, the inductors 21 and 23 are arranged with the inductor 22 interposed therebetween. Additionally, since the area ratio of the inner region of the inductor 21 to the inner region of the inductor 23 is smaller than the area ratio of the inner region of the inductor 22 to the inner region of the inductor 23, the coupling coefficient k23 between the inductors 22 and 23 greater than the coupling coefficient k13 between the inductors 21 and 23. Accordingly, it is possible to broaden the bandwidth of the amplification characteristics of the low-noise amplifier circuit 1B.

### 5. Implementation Example of Inductors 21, 22, and 23 According to Modification Example 3

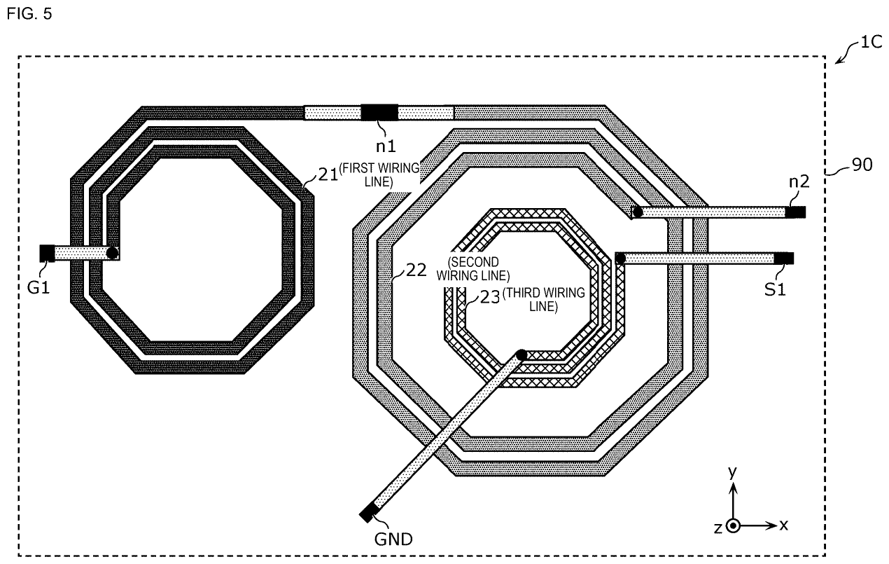

Next, an implementation example of the inductors 21 to 23 included in a low-noise amplifier circuit 1C according to Modification Example 3 will be described with reference to FIG. 5. FIG. 5 is a plan view of the low-noise amplifier circuit 1C according to Modification Example 3 of the embodiment. Specifically, FIG. 5 is a plan (perspective) view of the region in which the inductors 21 to 23 of the substrate 90 are formed, as viewed from the positive z-axis side.

The low-noise amplifier circuit 1C according to Modification Example 3 includes the circuit configuration illustrated in FIG. 1, and it only differs from the low-noise amplifier circuit 1 according to the embodiment in the arrangement configurations of the inductors 21 to 23. Therefore, in the following description of the low-noise amplifier circuit 1C according to the present modification example, explanation of configurations identical to those of the low-noise amplifier circuit 1 according to the embodiment will be omitted, and the description will focus on the arrangement configurations of the inductors 21 to 23 that differ from the low-noise amplifier circuit 1 according to the embodiment.

As illustrated in FIG. 5, the low-noise amplifier circuit 1C includes the substrate 90 in addition to the circuit configuration illustrated in FIG. 1.

As illustrated in FIG. 5, the inductor 21 is formed by a coil-shaped first wiring line disposed in or on the substrate 90. Additionally, the inductor 22 is formed by a coil-shaped second wiring line disposed in or on the substrate 90. Moreover, the inductor 23 is formed by a coil-shaped third wiring line disposed in or on the substrate 90. The inductors 21 to 23 are formed in an identical layer of the substrate 90.

Specifically, the inductor 21 is formed by a first wiring line that extends in a counterclockwise spiral from the outer side toward the inner side. The inductor 22 is formed by a second wiring line that extends in a clockwise spiral from the outer side toward the inner side. The first end of the inductor 21 and the first end of the inductor 22 are connected at the node n1. The second end of the inductor 21 is connected to the gate G1 of the FET 11 with connection wiring interposed therebetween. The second end of the inductor 22 is connected to the node n2 with connection wiring interposed therebetween. The inductor 23 is formed by a third wiring line that extends in a clockwise spiral from the outer side toward the inner side. The first end of the inductor 23 is connected to the source end S1 of the FET 11 with connection wiring interposed therebetween. The second end of the inductor 23 is connected to ground with connection wiring interposed therebetween.

Here, in a plan view of the substrate 90, the winding axis of the inductor 21 extending in the z-axis direction is encompassed within the outer region of the second wiring line. Additionally, in a plan view of the substrate 90, the winding axis of the inductor 23 extending in the z-axis direction is encompassed within the inner region of the second wiring line. Moreover, the first wiring line constituting the inductor 21 is disposed in the outer region of the second wiring line constituting the inductor 22. The third wiring line constituting the inductor 23 is disposed in the inner region of the second wiring line.

According to this, in a plan view of the substrate 90, since the inductors 21 and 23 are arranged with the inductor 22 interposed therebetween, it is possible to make the coupling coefficient k23 between the inductors 22 and 23 greater than the coupling coefficient k13 between the inductors 21 and 23. By doing so, it is possible to suppress a low-pass filter from being formed between the inductors 23 and 21, and it is also possible to ensure good linearity up to higher frequencies by the feedback loop formed by magnetic coupling between the inductors 23 and 22. Accordingly, it is possible to broaden the bandwidth of the amplification characteristics of the low-noise amplifier circuit 1C.

Note that each of the inductors 21 to 23 need not be configured by a wiring line formed only in a single layer of the substrate 90, but may instead be configured by multiple wiring lines formed across multiple layers of the substrate 90.

Additionally, the first wiring line, the second wiring line, and the third wiring line may be formed in different layers of the substrate 90 or at least portions of the first wiring line, the second wiring line, or the third wiring line may be formed in an identical layer of the substrate 90.

Moreover, the winding directions of the inductors 21 to 23 are not limited to the winding directions described above.

Each of the inductors 21 and 23 may be a surface-mounted chip inductor disposed on the substrate 90.

### 6. Implementation Example of Inductors 21, 22, and 23 According to Modification Example 4

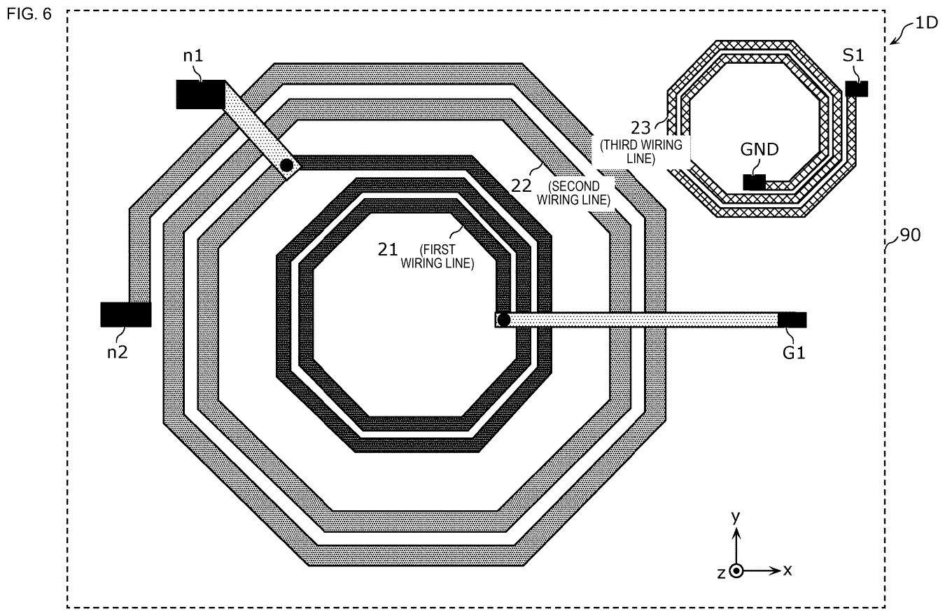

Next, an implementation example of the inductors 21 to 23 included in a low-noise amplifier circuit 1D according to Modification Example 4 will be described with reference to FIG. 6. FIG. 6 is a plan view of the low-noise amplifier circuit 1D according to Modification Example 4 of the embodiment. Specifically, FIG. 6 is a plan (perspective) view of the region in which the inductors 21 to 23 of the substrate 90 are formed, as viewed from the positive z-axis side.

The low-noise amplifier circuit 1D according to Modification Example 4 includes the circuit configuration illustrated in FIG. 1, and it only differs from the low-noise amplifier circuit 1 according to the embodiment in the arrangement configurations of the inductors 21 to 23. Additionally, the low-noise amplifier circuit 1D according to the present modification example differs from the low-noise amplifier circuit 1C according to Modification Example 3 only in that the arrangement relationship between the inductors 21 and 23 with respect to the inductor 22 is reversed. Therefore, in the following description of the low-noise amplifier circuit 1D according to the present modification example, explanation of configurations identical to those of the low-noise amplifier circuit 1C according to Modification Example 3 will be omitted, and the description will focus on the arrangement configurations of the inductors 21 to 23 that differ from the low-noise amplifier circuit 1C according to Modification Example 3.

As illustrated in FIG. 6, the inductor 21 is formed by a first wiring line that extends in a clockwise spiral from the outer side toward the inner side. The inductor 22 is formed by a second wiring line that extends in a counterclockwise spiral from the inner side toward the outer side. The first end of the inductor 21 and the first end of the inductor 22 are connected at the node n1 with connection wiring interposed therebetween. The second end of the inductor 21 is connected to the gate G1 of the FET 11 with connection wiring interposed therebetween. The second end of the inductor 22 is connected to the node n2. The inductor 23 is formed by a third wiring line that extends in a clockwise spiral from the outer side toward the inner side. The first end of the inductor 23 is connected to the source end S1 of the FET 11. The second end of the inductor 23 is connected to ground.

Here, in a plan view of the substrate 90, the winding axis of the inductor 21 extending in the z-axis direction is encompassed within the inner region of the second wiring line. Additionally, the winding axis of the inductor 23 extending in the z-axis direction is encompassed within the outer region of the second wiring line. Moreover, the first wiring line constituting the inductor 21 is disposed in the inner region of the second wiring line constituting the inductor 22. The third wiring line constituting the inductor 23 is disposed in the outer region of the second wiring line.

According to this, in a plan view of the substrate 90, since the inductors 21 and 23 are arranged with the inductor 22 interposed therebetween, it is possible to make the coupling coefficient k23 between the inductors 22 and 23 greater than the coupling coefficient k13 between the inductors 21 and 23. By doing so, it is possible to suppress a low-pass filter from being formed between the inductors 23 and 21, and it is also possible to ensure good linearity up to higher frequencies by the feedback loop formed by magnetic coupling between the inductors 23 and 22. Accordingly, it is possible to broaden the bandwidth of the amplification characteristics of the low-noise amplifier circuit 1D.

Note that each of the inductors 21 to 23 need not be configured by a wiring line formed only in a single layer of the substrate 90, but may instead be configured by multiple wiring lines formed across multiple layers of the substrate 90.

Additionally, the first wiring line, the second wiring line, and the third wiring line may be formed in different layers of the substrate 90 or at least portions of the first wiring line, the second wiring line, or the third wiring line may be formed in an identical layer of the substrate 90.

Moreover, the winding directions of the inductors 21 to 23 are not limited to the winding directions described above.

Each of the inductors 21 and 23 may be a surface-mounted chip inductor disposed on the substrate 90.

### 7. Implementation Example of Inductors 21, 22, and 23 According to Modification Example 5

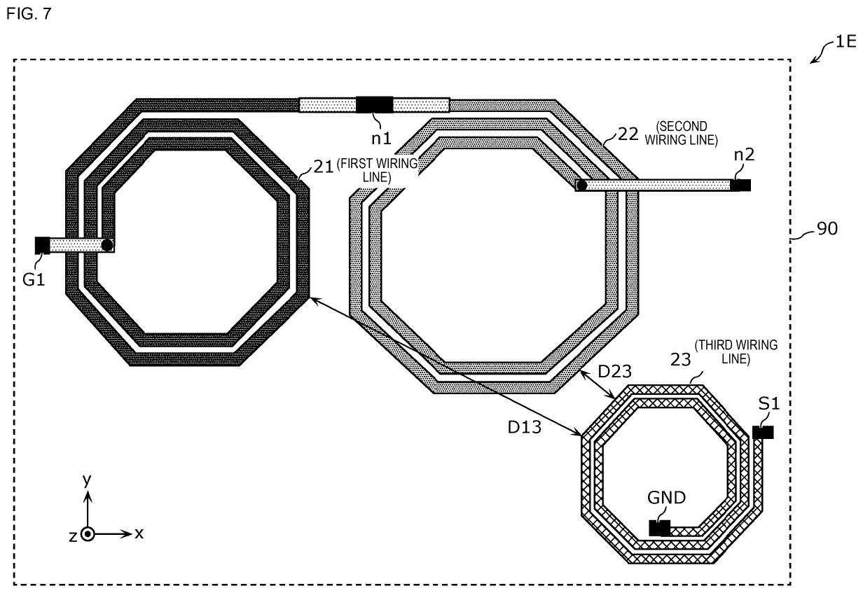

Next, an implementation example of the inductors 21 to 23 included in a low-noise amplifier circuit 1E according to Modification Example 5 will be described with reference to FIG. 7. FIG. 7 is a plan view of the low-noise amplifier circuit 1E according to Modification Example 5 of the embodiment. Specifically, FIG. 7 is a plan (perspective) view of the region in which the inductors 21 to 23 of the substrate 90 are formed, as viewed from the positive z-axis side.

The low-noise amplifier circuit 1E according to Modification Example 5 includes the circuit configuration illustrated in FIG. 1, and it only differs from the low-noise amplifier circuit 1 according to the embodiment in the arrangement configurations of the inductors 21 to 23. Therefore, in the following description of the low-noise amplifier circuit 1E according to the present modification example, explanation of configurations identical to those of the low-noise amplifier circuit 1 according to the embodiment will be omitted, and the description will focus on the arrangement configurations of the inductors 21 to 23 that differ from the low-noise amplifier circuit 1 according to the embodiment.

As illustrated in FIG. 7, the low-noise amplifier circuit 1E includes the substrate 90 in addition to the circuit configuration illustrated in FIG. 1.

As illustrated in FIG. 7, the inductor 21 is formed by a coil-shaped first wiring line disposed in or on the substrate 90. Additionally, the inductor 22 is formed by a coil-shaped second wiring line disposed in or on the substrate 90. Moreover, the inductor 23 is formed by a coil-shaped third wiring line disposed in or on the substrate 90. The inductors 21 to 23 are formed in an identical layer of the substrate 90.

Specifically, the inductor 21 is formed by a first wiring line that extends in a counterclockwise spiral from the outer side toward the inner side. The inductor 22 is formed by a second wiring line that extends in a clockwise spiral from the outer side toward the inner side. The first end of the inductor 21 and the first end of the inductor 22 are connected at the node n1 with connection wiring interposed therebetween. The second end of the inductor 21 is connected to the gate G1 of the FET 11 with connection wiring interposed therebetween. The second end of the inductor 22 is connected to the node n2 with connection wiring interposed therebetween. The inductor 23 is formed by a third wiring line that extends in a clockwise spiral from the outer side toward the inner side. The first end of the inductor 23 is connected to the source end S1 of the FET 11. The second end of the inductor 23 is connected to ground.

Here, a distance D23 between the second wiring line and the third wiring line is smaller than a distance D13 between the first wiring line and the third wiring line. In other words, the distance D23 between the inductors 22 and 23 is smaller than the distance D13 between the inductors 21 and 23.

According to this, since the distance D23 is smaller than the distance D13, it is possible to make the coupling coefficient k23 between the inductors 22 and 23 greater than the coupling coefficient k13 between the inductors 21 and 23. By doing so, it is possible to suppress a low-pass filter from being formed between the inductors 23 and 21, and it is also possible to ensure good linearity up to higher frequencies by the feedback loop formed by magnetic coupling between the inductors 23 and 22. Accordingly, it is possible to broaden the bandwidth of the amplification characteristics of the low-noise amplifier circuit 1E.

Note that each of the inductors 21 to 23 need not be configured by a wiring line formed only in a single layer of the substrate 90, but may instead be configured by multiple wiring lines formed across multiple layers of the substrate 90.

Additionally, the first wiring line, the second wiring line, and the third wiring line may be formed in different layers of the substrate 90 or at least portions of the first wiring line, the second wiring line, or the third wiring line may be formed in an identical layer of the substrate 90.

Moreover, the winding directions of the inductors 21 to 23 are not limited to the winding directions described above.

Here, in a plan view of the substrate 90, the winding axis of one of the inductors 21 to 23 may not be encompassed within any of the inner regions of the wiring lines forming the other two inductors.

Each of the inductors 21 to 23 may be a surface-mounted chip inductor disposed on the substrate 90.

### 8. Implementation Example of Inductors 21, 22, and 23 According to Modification Example 6

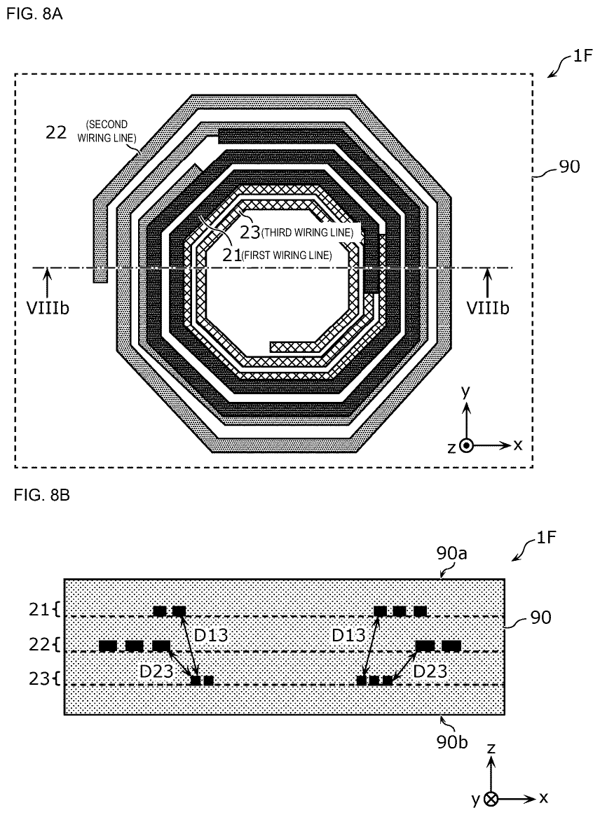

Next, an implementation example of the inductors 21 to 23 included in a low-noise amplifier circuit 1F according to Modification Example 6 will be described with reference to FIGS. 8A and 8B. FIG. 8A is a plan view of the low-noise amplifier circuit 1F according to Modification Example 6 of the embodiment. FIG. 8B is a cross-sectional view of the low-noise amplifier circuit 1F according to Modification Example 6 of the embodiment. Specifically, FIG. 8A is a plan (perspective) view of the region in which the inductors 21 to 23 of the substrate 90 are formed, as viewed from the positive z-axis side, and FIG. 8B is a cross-sectional view taken along line VIIIb-VIIIb of FIG. 8A. In FIG. 8A, for only the arrangement relationship among the inductors 21 to 23 is illustrated for ease of understanding.

The low-noise amplifier circuit 1F according to Modification Example 6 includes the circuit configuration illustrated in FIG. 1, and it only differs from the low-noise amplifier circuit 1 according to the embodiment in the arrangement configurations of the inductors 21 to 23. Therefore, in the following description of the low-noise amplifier circuit 1F according to the present modification example, explanation of configurations identical to those of the low-noise amplifier circuit 1 according to the embodiment will be omitted, and the description will focus on the arrangement configurations of the inductors 21 to 23 that differ from the low-noise amplifier circuit 1 according to the embodiment.

As illustrated in FIGS. 8A and 8B, the low-noise amplifier circuit 1F includes the substrate 90 having main surfaces 90a (first main surface) and 90b (second main surface) facing each other, in addition to the circuit configuration illustrated in FIG. 1.

As illustrated in FIG. 8A, the inductor 21 is formed by a coil-shaped first wiring line disposed in or on the substrate 90. Additionally, the inductor 22 is formed by a coil-shaped second wiring line disposed in or on the substrate 90. Moreover, the inductor 23 is formed by a coil-shaped third wiring line disposed in or on the substrate 90. In a plan (perspective) view of the main surface 90a, the winding axis of the inductor 21 and the winding axis of the inductor 23, which extend in the z-axis direction, are encompassed within the inner region of the second wiring line constituting the inductor 22.

Here, as illustrated in FIG. 8B, the first wiring line is disposed on the main surface 90a side of the second wiring line, and the third wiring line is disposed on the main surface 90b side of the second wiring line. In other words, the inductor 21 is disposed on the main surface 90a side of the inductor 22, and the inductor 23 is disposed on the main surface 90b side of the inductor 22.

According to this, since the distance D23 between the inductors 22 and 23 is smaller than the distance D13 between the inductors 21 and 23, it is possible to make the coupling coefficient k23 between the inductors 22 and 23 greater than the coupling coefficient k13 between the inductors 21 and 23. By doing so, it is possible to suppress a low-pass filter from being formed between the inductors 23 and 21, and it is also possible to ensure good linearity up to higher frequencies by the feedback loop formed by magnetic coupling between the inductors 23 and 22. Accordingly, it is possible to broaden the bandwidth of the amplification characteristics of the low-noise amplifier circuit 1F.

Note that each of the inductors 21 to 23 need not be configured by a wiring line formed only in a single layer of the substrate 90, but may instead be configured by multiple wiring lines formed across multiple layers of the substrate 90.

Moreover, the winding directions of the inductors 21 to 23 are not limited to the winding directions described above.

### 9. Effects, etc.

As described above, the low-noise amplifier circuit 1 according to the present embodiment includes: the input terminal 101, the output terminal 102, the amplifier 10 connected between the input terminal 101 and the output terminal 102, the transmission line transformer 20 including the inductors 21 and 22 and connected between the input terminal 101 and the input end of the amplifier 10, and the inductor 23 connected between the ground connection end of the amplifier 10 and ground. The first end of the inductor 21 and the first end of the inductor 22 are connected to the input terminal 101. The second end of the inductor 21 is connected to the input end of the amplifier 10. The second end of the inductor 22 is connected to ground. The coupling coefficient k23 between the inductors 22 and 23 is greater than the coupling coefficient k13 between the inductors 21 and 23.

According to this, since the coupling coefficient k13 is smaller than the coupling coefficient k23, a low-pass filter is suppressed from being formed between the inductors 23 and 21. Additionally, since the coupling coefficient k23 is greater than the coupling coefficient k13, it is possible to ensure good linearity up to higher frequencies by the feedback loop between the inductors 23 and 22. Therefore, it is possible to broaden the bandwidth of the amplification characteristics of the low-noise amplifier circuit 1.

Additionally, for example, the low-noise amplifier circuit 1, the low-noise amplifier circuit 1B according to Modification Example 2, the low-noise amplifier circuit 1C according to Modification Example 3, and the low-noise amplifier circuit 1D according to Modification Example 4 further include the substrate 90. The inductor 21 is formed by a first wiring line disposed in or on the substrate 90. The inductor 22 is formed by a coil-shaped second wiring line disposed in or on the substrate 90. The inductor 23 is formed by a third wiring line disposed in or on the substrate 90. One of the first wiring line and the third wiring line is disposed in the inner region of the second wiring line in a plan view of the substrate 90. The other of the first wiring line and the third wiring line is disposed in the outer region of the second wiring line in a plan view of the substrate 90.

According to this, in a plan view of the substrate 90, since the inductors 21 and 23 are arranged with the inductor 22 interposed therebetween, it is possible to make the coupling coefficient k23 between the inductors 22 and 23 greater than the coupling coefficient k13 between the inductors 21 and 23. By doing so, it is possible to suppress a low-pass filter from being formed between the inductors 23 and 21, and it is also possible to ensure good linearity up to higher frequencies by the feedback loop formed by magnetic coupling between the inductors 23 and 22. Accordingly, it is possible to broaden the bandwidth of the amplification characteristics of the low-noise amplifier circuit 1 (1B, 1C, and 1D).

Moreover, for example, in the low-noise amplifier circuit 1B, the first wiring line and the third wiring line are coil-shaped. In a plan view of the substrate 90, the winding axis of the inductor 21 and the winding axis of the inductor 23 are encompassed within the inner region of the second wiring line.

According to this, in a plan view of the substrate 90, since the inductors 21 and 23 are arranged with the inductor 22 interposed therebetween, it is possible to make the coupling coefficient k23 between the inductors 22 and 23 greater than the coupling coefficient k13 between the inductors 21 and 23. Accordingly, it is possible to broaden the bandwidth of the amplification characteristics of the low-noise amplifier circuit 1B.

In addition, for example, the low-noise amplifier circuit 1E according to Modification Example 5 further includes the substrate 90. The inductors 21, 22, and 23 are formed by wiring lines disposed in or on the substrate 90. The distance D23 between the inductors 22 and 23 is smaller than the distance D13 between the inductors 21 and 23.

According to this, since the distance D23 is smaller than the distance D13, it is possible to make the coupling coefficient k23 between the inductors 22 and 23 greater than the coupling coefficient k13 between the inductors 21 and 23. By doing so, it is possible to suppress a low-pass filter from being formed between the inductors 23 and 21, and it is also possible to ensure good linearity up to higher frequencies by the feedback loop formed by magnetic coupling between the inductors 23 and 22. Accordingly, it is possible to broaden the bandwidth of the amplification characteristics of the low-noise amplifier circuit 1E.

Furthermore, for example, the low-noise amplifier circuit 1F according to Modification Example 6 further includes the substrate 90 having the main surfaces 90a and 90b facing each other. The inductor 21 is formed by a coil-shaped first wiring line disposed in or on the substrate 90. The inductor 22 is formed by a coil-shaped second wiring line disposed in or on the substrate 90. The inductor 23 is formed by a coil-shaped third wiring line disposed in or on the substrate 90. In a plan view of the main surface 90a, the winding axis of the inductor 21 and the winding axis of the inductor 23 are encompassed within the inner region of the second wiring line. The first wiring line is disposed on the main surface 90a side of the second wiring line, and the third wiring line is disposed on the main surface 90b side of the second wiring line.

According to this, since the distance D23 between the inductors 22 and 23 is smaller than the distance D13 between the inductors 21 and 23, it is possible to make the coupling coefficient k23 between the inductors 22 and 23 greater than the coupling coefficient k13 between the inductors 21 and 23. By doing so, it is possible to suppress a low-pass filter from being formed between the inductors 23 and 21, and it is also possible to ensure good linearity up to higher frequencies by the feedback loop formed by magnetic coupling between the inductors 23 and 22. Accordingly, it is possible to broaden the bandwidth of the amplification characteristics of the low-noise amplifier circuit 1F.

Additionally, for example, in the low-noise amplifier circuit according to the embodiment, the amplifier 10 includes the FET 11; the gate end of the FET 11 is the input end of the amplifier 10; the source end of the FET 11 is the ground connection end of the amplifier 10; and the drain end of the FET 11 is the output end of the amplifier 10.

According to this, it becomes possible to configure a low-noise amplifier circuit using a single transistor stage.

Furthermore, for example, in the low-noise amplifier circuit 1, the amplifier 10 includes the FETs 11 and 12; the drain end D1 of the FET 11 is connected to the source end S2 of the FET 12; the gate end G1 of the FET 11 is the input end of the amplifier 10; the source end S1 of the FET 11 is the ground connection end of the amplifier 10; and the drain end D2 of the FET 12 is the output end of the amplifier 10.

According to this, it becomes possible to configure a low-noise amplifier circuit using a two-stage cascode-connected transistor configuration.

Moreover, for example, the low-noise amplifier circuit 1 further includes the capacitor 31 connected between the input terminal 101 and the first end of the inductor 21, the bias terminal 103 connected to the second end of the inductor 22, and the capacitor 33 connected between the second end of inductor 22 and the bias terminal 103, and ground.

According to this, it becomes possible to supply a bias voltage (current) to the amplifier 10 via the transmission line transformer 20.

Moreover, for example, the low-noise amplifier circuit 1A further includes the capacitor 35 connected between the second end of the inductor 21 and the input end of the amplifier 10, and the bias terminal 103 connected between the capacitor 35 and the input end of the amplifier 10.

According to this, it becomes possible to supply a bias voltage (current) to the amplifier 10 without going through the transmission line transformer 20.

Additionally, for example, in the low-noise amplifier circuits 1 and 1A to 1F, the coupling coefficient k12 between the inductors 21 and 22 is greater than the coupling coefficient k23 between the inductors 22 and 23.

Accordingly, a greater degree of freedom in phase shifting and impedance transformation in the transmission line transformer 20 may be realized.

### Other Embodiments

Although the low-noise amplifier circuit according to the present disclosure has been described above based on the embodiment, the low-noise amplifier circuit of the present disclosure is not limited to the embodiment described above. Other embodiments realized by combining any components of the above-described embodiment, and modification examples obtained by applying various modifications conceived by those skilled in the art without departing from the spirit of the present disclosure, as well as various devices incorporating the above-described low-noise amplifier circuit, are also included in the present disclosure.

For example, in the circuit configuration of the low-noise amplifier circuit according to the above-described embodiment, other circuit elements and wiring may be inserted in the paths connecting the circuit elements and signal paths disclosed in the drawings. For example, the low-noise amplifier circuit 1 may include a bias circuit that applies a bias voltage to the FET 11.

The present disclosure is widely applicable to communication devices such as mobile phones, as a low-noise amplifier circuit disposed in a front-end section.

What is claimed is:

1. A low-noise amplifier circuit comprising:
an input terminal;
an output terminal;
an amplifier connected between the input terminal and the output terminal;
a transmission line transformer including a first inductor and a second inductor, the transmission line transformer being connected between the input terminal and an input end of the amplifier; and
a third inductor connected between a ground connection end and a ground,
wherein a first end of the first inductor and a first end of the second inductor are connected to the input terminal;
a second end of the first inductor is connected to the input end of the amplifier;
a second end of the second inductor is connected to the ground; and
the second inductor is magnetically coupled to the third inductor more strongly than the first inductor is magnetically coupled to the third inductor.

2. The low-noise amplifier circuit according to claim 1, wherein a coupling coefficient between the second inductor and the third inductor is greater than a coupling coefficient between the first inductor and the third inductor.

3. The low-noise amplifier circuit according to claim 1, further comprising:
a substrate, wherein:
the first inductor is formed by a first wiring line disposed in or on the substrate;
the second inductor is formed by a coil-shaped second wiring line disposed in or on the substrate;
the third inductor is formed by a third wiring line disposed in or on the substrate;
a first one of the first wiring line and the third wiring line is disposed in an inner region of the second wiring line in a plan view of the substrate; and
a second one of the first wiring line and the third wiring line is disposed in an outer region of the second wiring line in a plan view of the substrate.

4. The low-noise amplifier circuit according to claim 3, wherein:
the first wiring line and the third wiring line are coil-shaped; and
in a plan view of the substrate, a winding axis of the first inductor and a winding axis of the third inductor are encompassed within the inner region of the second wiring line.

5. The low-noise amplifier circuit according to claim 1, further comprising:
a substrate, wherein:
the first inductor, the second inductor, and the third inductor are formed by wiring lines disposed in or on the substrate; and
a distance between the second inductor and the third inductor is smaller than a distance between the first inductor and the third inductor.

6. The low-noise amplifier circuit according to claim 1, further comprising:
a substrate having a first main surface and a second main surface facing each other,
wherein the first inductor is formed by a coil-shaped first wiring line disposed in or on the substrate;
the second inductor is formed by a coil-shaped second wiring line disposed in or on the substrate;
the third inductor is formed by a coil-shaped third wiring line disposed in or on the substrate;
in a plan view of the first main surface, a winding axis of the first inductor and a winding axis of the third inductor are encompassed within an inner region of the second wiring line;
the first wiring line is disposed on the first main surface side of the second wiring line; and
the third wiring line is disposed on the second main surface side of the second wiring line.

7. The low-noise amplifier circuit according to claim 1, wherein a physical distance between the second inductor and the third inductor is smaller than a physical distance between the first inductor and the third inductor.

8. The low-noise amplifier circuit according to claim 1, further comprising a substrate, wherein the second inductor is a coil-shaped wiring line disposed on the substrate, and the first and third inductors are respectively disposed in an inner region and an outer region of the second inductor.

9. The low-noise amplifier circuit according to claim 1, wherein in a plan view, a winding axis of the first inductor and a winding axis of the third inductor are both encompassed within an inner region of the second inductor.

10. The low-noise amplifier circuit according to claim 9, wherein an area ratio of an inner region of the third inductor to an inner region of the first inductor is smaller than an area ratio of the inner region of the third inductor to an inner region of the second inductor.

11. The low-noise amplifier circuit according to claim 1, wherein:
the amplifier includes a first FET;
a gate end of the first FET is the input end;
a source end of the first FET is the ground connection end; and
a drain end of the first FET is an output end of the amplifier.

12. The low-noise amplifier circuit according to claim 1, wherein:
the amplifier includes a first field effect transistor (FET) and a second FET;
a drain end of the first FET is connected to a source end of the second FET;
a gate end of the first FET is the input end;
a source end of the first FET is the ground connection end; and
a drain end of the second FET is an output end of the amplifier.

13. The low-noise amplifier circuit according to claim 1, further comprising:
a first capacitor connected between the input terminal and the first end of the first inductor;
a bias terminal connected to the second end of the second inductor; and
a second capacitor connected between the second end of the second inductor and the bias terminal, and ground.

14. The low-noise amplifier circuit according to claim 1, further comprising:
a first capacitor connected between the second end of the first inductor and the input end of the amplifier; and
a bias terminal connected between the first capacitor and the input end of the amplifier.

15. A low-noise amplifier circuit comprising:
an input terminal;
an output terminal;
an amplifier connected between the input terminal and the output terminal;
a transmission line transformer including a first inductor and a second inductor, the transmission line transformer being connected between the input terminal and an input end of the amplifier; and
a third inductor connected between a ground connection end of the amplifier and a ground,
wherein a first end of the first inductor and a first end of the second inductor are connected to the input terminal;
a second end of the first inductor is connected to the input end of the amplifier;
a second end of the second inductor is connected to the ground;
wherein, in a plan view, the second inductor is physically interposed between the first inductor and the third inductor.

16. The low-noise amplifier circuit according to claim 1, wherein
the first inductor is formed by a first wiring line disposed in or on a substrate;
the second inductor is formed by a coil-shaped second wiring line disposed in or on the substrate;
the third inductor is formed by a third wiring line disposed in or on the substrate;
a first one of the first wiring line and the third wiring line is disposed in an inner region of the second wiring line in a plan view of the substrate; and
a second one of the first wiring line and the third wiring line is disposed in an outer region of the second wiring line in a plan view of the substrate.

17. The low-noise amplifier circuit according to claim 16, wherein:
the first wiring line and the third wiring line are coil-shaped; and
in a plan view of the substrate, a winding axis of the first inductor and a winding axis of the third inductor are encompassed within the inner region of the second wiring line.

18. The low-noise amplifier circuit according to claim 15, wherein:
a coupling coefficient between the first inductor and the second inductor is greater than a coupling coefficient between the second inductor and the third inductor.

19. The low-noise amplifier circuit according to claim 15, wherein the first, second, and third inductors are formed by wiring lines disposed on a same layer of a substrate.

20. The low-noise amplifier circuit according to claim 15, wherein an outer diameter of the first inductor is smaller than an inner diameter of the second inductor.
